(19) United States
(12) Patent Application Publication
(10) Pub. No.: US 2006/0007663 A1
(43) Pub. Date: Jan. 12, 2006

(54) Electronic control device for motor vehicles

(75) Inventor: Gerhard Mersch, Uetze (DE)

Correspondence Address: CARLSON, GASKEY & OLDS, P.C., 400 WEST MAPLE ROAD, SUITE 350, BIRMINGHAM, MI, 48009, US

(73) Assignee: ArvinMeritor GmbH

(21) Appl. No.: 11/169,483

(22) Filed: Jun. 29, 2005

(30) Foreign Application Priority Data
Jul. 9, 2004 (DE) 10 2004 033 369.6

(51) Int. Cl. H05K 7/10

(52) U.S. Cl. 361/785

(57) ABSTRACT

An electronic control device for motor vehicles includes a controller arranged on a basic circuit board that controls standard functions of a vehicular component. The electronic control device further includes a first plug connector linked with the controller. Also included is an add-on module with at least one additional circuit board on which electrical elements are arranged to control additional functions of the vehicular component. The add-on module is attached on the first plug connector and has a second plug connector.

### BACKGROUND OF THE INVENTION

The application claims priority to German Application No. 10 2004 033 369.6, which was filed on Jul. 9, 2004.

The invention relates to an electronic control device for motor vehicles, in particular a door control device, which includes a controller arranged on a basic circuit board to control standard functions of a vehicular component, and a first plug connector linked with the controller.

Typically, electronic control devices are used in motor vehicles to control actuators of a vehicular component. To improve integrity, electronic control devices have been developed together with a drive motor to form a pre-assembled unit that has a very compact construction. With such electronic control devices it is possible to provide standard functions of a particular vehicular component. In the example of a vehicle door, the standard function could be an electric window lifting function, provided with the aid of an electric motor controlled by a controller of the electronic control device.

One disadvantage with these electronic control devices is that a design configuration is chosen based on a limited size of an associated basic circuit board. This is why additional electrical elements, which are required for controlling additional functions of the particular vehicular component, are not accommodated on the basic circuit board due to the lack of space. Moreover, these additional electrical elements, which are required only for certain types of vehicles or certain equipment variants, significantly increase production costs of the electronic control device.

### SUMMARY OF THE INVENTION

It is the object of the invention to provide control of additional functions of a vehicular component in a cost-effective way.

This is achieved according to the invention by a control device that includes an add-on module with at least one additional circuit board on which electrical elements are arranged to control additional functions of the vehicular component. The add-on module is attached on a first plug connector and includes a second plug connector. Moving the additional elements to a circuit board of the add-on module has the advantage of a standard control device, which controls the standard functions, and can continue to be used with only slight modifications. Thus, established amenities of the standard control device continue to take effect. As the add-on module is only installed when additional functions are actually desired, it is possible to avoid unnecessary costs. The invention also provides the option of utilizing different specific add-on modules depending on the nature and complexity of the additional functions.

One particularly advantageous embodiment of the invention utilizes specific connection lines of the first plug connector, which are associated with the standard functions. These specific connection lines are looped through the add-on module to the second plug connector. The control device according to the invention, which is connected to a vehicular bus system through the second plug connector, can thus be addressed with respect to the standard functions in a manner similar to a standard control device.

The provision of the additional functions is preferably accomplished in that the first plug connector has at least one connection pin connected to the circuit board of the add-on module. This establishes a serial communication between the controller and add-on module in an easy way.

A consistently easy installation results from the fact that the physical format of the second plug connector is identical to the physical format of the first plug connector, i.e. the first and second plug connectors have the same plug format, which so far has been used for connecting a standard control device, and can also be used for the control device according to the invention. In this case, a connection plug and the second plug connector may have additional occupied connection pins for a connection to the add-on module. These additional pins are unoccupied when a standard control device without an add-on module is utilized.

According to a preferred embodiment of the invention the add-on module has at least one integrated circuit, which is addressed by a controller as a slave input/output (I/O) unit.

These and other features of the present invention can be best understood from the following specification and drawings, the following of which is a brief description.

### BRIEF DESCRIPTION OF THE DRAWINGS

FIG. 1 is a schematic representation of a motor unit and a control device according to prior art.

FIG. 2 is a schematic representation of a motor unit and a control device according to the invention.

FIG. 3 is a schematic, perspective view of a control device according to the invention, without a housing.

FIG. 4 is a logic block diagram of a control device according to the invention.

### DETAILED DESCRIPTION OF THE PREFERRED EMBODIMENT

FIG. 1 illustrates a motor unit including an electric motor 10 that is part of a system for controlling functions on a door of a motor vehicle. Linked with the electric motor 10 is a standard control device 12 with which standard functions, such as reading-out of switches and controlling window motion with the aid of the electric motor 10, are realized. The control device 12 is connected to a vehicular bus system, such as an Inter-Integrated Circuit (I2C) or Local Interconnect Network (LIN), for example, (not shown) through a plug connector 14.

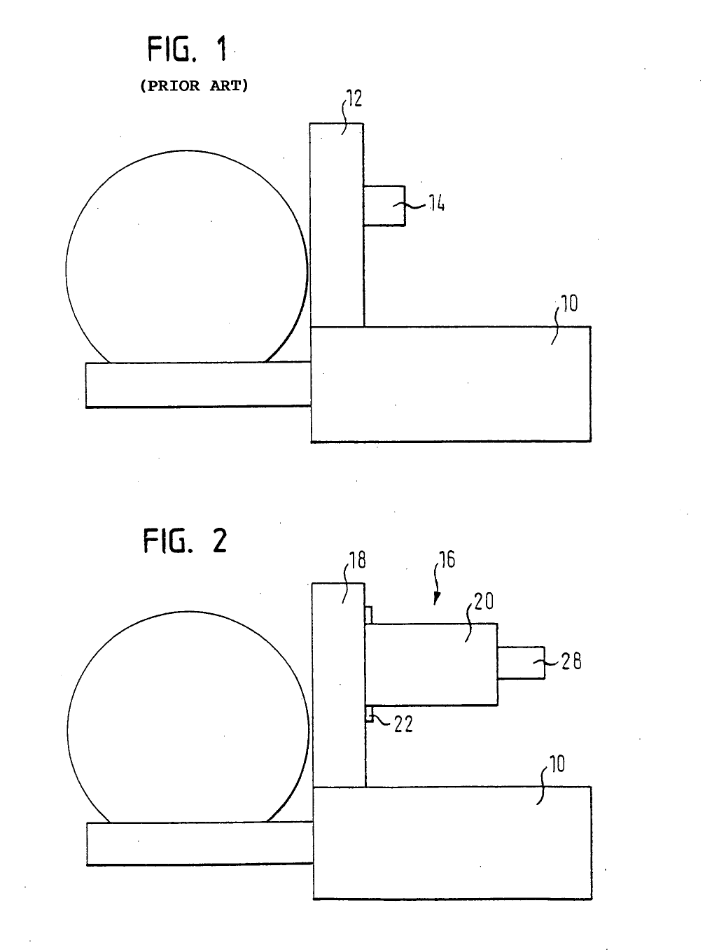

FIG. 2 shows a motor unit comprising a control device 16 according to the invention. The control device 16 is composed of a standard part 18, which is generally equivalent to the control device 12 from FIG. 1, and add-on module 20. The add-on module 20 is attached on a first plug connector 14 of the standard part 18, and is fastened to a housing of the standard part 18 by means of a screw or clip connection 22.

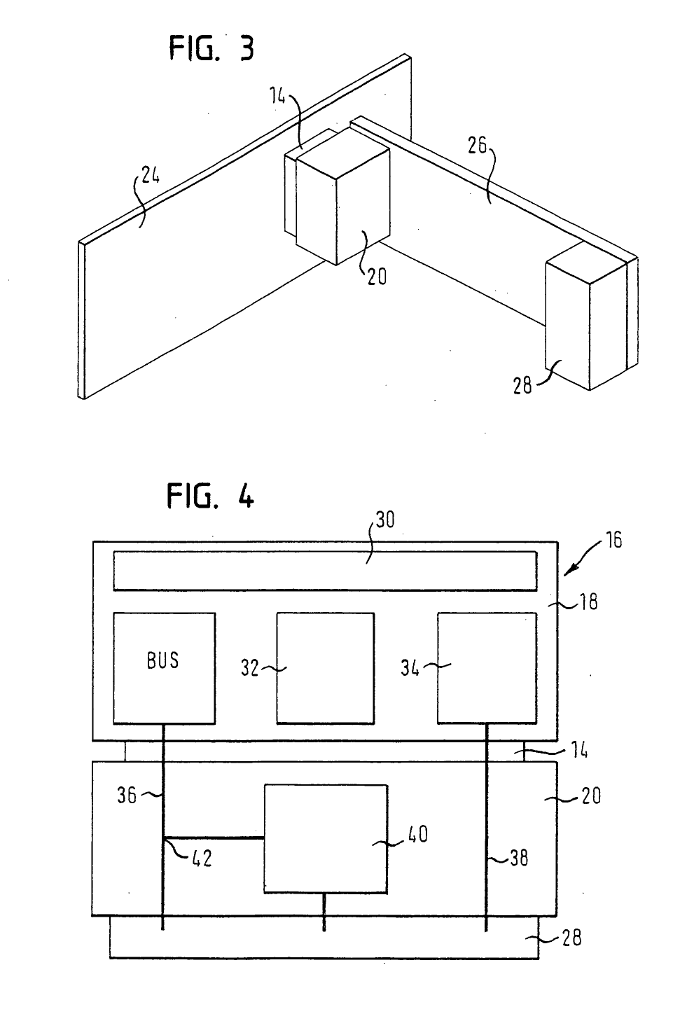

The basic structure of the control device 16 according to the invention is shown in FIG. 3. Arranged on a basic circuit board 24 of the standard part 18 is a controller that activates the electric motor 10 (FIG. 2). Attached on the first plug connector 14 is an add-on module 20 that has an additional circuit board 26 and a second plug connector 28 linked with the additional circuit board 26.

Additional elements (not shown) are arranged on the additional circuit board 26, which allow control of additional functions, such as an electric locking of the door or an electric adjustment of an outside mirror. The second plug connector 28 has the same physical format as the first plug connector 14. In other words, the same connection plug, with which the standard control device 12 of FIG. 1 is connected to the vehicular bus system, matches with the second plug connector 28. Thus, the control device 16 according to the invention can be connected through the second plug connector 28 to the vehicular bus system just like the connection of the standard control device 12 through the first plug connector 14.

FIG. 4 shows a logic structure of the control device 16 according to the invention. The standard part 18 comprises, inter alia, a serial interface 30 for connecting the electric motor 10, a memory 32 with program data (for instance a squeeze protection algorithm), and a switch interface 34 for the reading-out of switches. Lines 36 and 38 connect the standard part 18 to the bus system and connect a switch interface 34, respectively. The lines 36 and 38 are passed to the first plug connector 14 and looped through the add-on module 20 to the second plug connector 28.

In contrast to a standard control device 12 there are one or more additionally occupied connection pins in the first plug connector 14 that allow a serial communication of the standard part 18 with the add-on module 20. At least one integrated circuit 40 is arranged on the additional circuit board 26 of the add-on module 20. the integrated circuit 40 is connected to bus line 36 through a node 42 and works as a slave-I/O-unit. The slave-I/O-unit only carries out commands of a controller of the standard part 18, and does not contain any additional logic. In case the controller asks for switching on of a motor for a door lock, for example, the integrated circuit 40 receives and carries out the command. The logic for calling the command resides exclusively in the controller of the standard part 18 and is defined in particular by the data in the memory 32, which is adapted to the respective add-on module 20.

In order to ensure that the communication between the controller and the add-on module 20 does not interfere with another serial communication between other control units of the vehicle, it is possible to provide two serial lines between the controller and the add-on module 20, one internal and one external line.

The invention has been described for the example of a door control device. The concept underlying the invention, however, can also be used with control devices for other vehicular components.

Although a preferred embodiment of this invention has been disclosed, a worker of ordinary skill in this art would recognize that certain modifications would come within the scope of this invention. For that reason, the following claims should be studied to determine the true scope and content of this invention.

What is claimed is:

1. An electronic control device for motor vehicles comprising:
a controller arranged on a basic circuit board to control standard functions of a vehicular component;
a first plug connector linked with the controller; and
an add-on module including at least one additional circuit board on which electrical elements are arranged to control additional functions of the vehicular component, wherein the add-on module is attached on the first plug connector and has a second plug connector.

2. The electronic control device according to claim 1 wherein the first plug connector includes specific connection lines that are associated with the standard functions, and wherein the specific connection lines are looped through the add-on module to the second plug connector.

3. The electronic control device according to claim 1 wherein the first plug connector has at least one connection pin connected to the at least one additional circuit board of the add-on module.

4. The electronic control device according to claim 1 wherein a physical format of the second plug connector is identical to a physical format of the first plug connector.

5. The electronic control device according to claim 1 wherein the add-on module has at least one integrated circuit that is addressed by the controller as a slave input/output unit.

6. The electronic control device according to claim 1 wherein the add-on module is fastened to a housing of the electronic control device.

7. The electronic control device according to claim 1 wherein the controller activates an electric motor.

8. The electronic control device according to claim 7 wherein the electric motor comprises a drive motor for a window lifter drive.

9. The electronic control device according to claim 1 wherein the electronic control device comprises a door control device.

10. The electronic control device according to claim 1 wherein the second plug connector is adapted for connection to a vehicle bus system.
